(19) United States
(12) Patent Application Publication
(10) Pub. No.: US 2020/0118200 A1
(43) Pub. Date: Apr. 16, 2020

(54) LEASE MANAGEMENT METHOD AND SYSTEM OF ELECTRIC POWER MOTION APPARATUS

(71) Applicant: YUJET INTERNATIONAL LIMITED, Central (HK)

(72) Inventor: Yu TIAN, Hong Kong (HK)

(21) Appl. No.: 16/378,143

(22) Filed: Apr. 8, 2019

(30) Foreign Application Priority Data
Oct. 15, 2018 (CN) 201811197192.4

(51) Int. Cl. G06Q 30/06; G01R 31/00; G01R 31/367; G01S 19/42

(52) U.S. Cl. CPC G06Q 30/0645; G01S 19/42; G01R 31/367; G01R 31/005

(57) ABSTRACT

A lease management method of an electric power motion apparatus includes: checking idle time periods of the electric power motion apparatus at a lease station via a lease application and reserving lease of the electric power motion apparatus; unlocking the electric power motion apparatus via the lease application; acquiring lease information, a battery state and location information of the electric power motion apparatus, calculating time for replacing a battery of the electric power motion apparatus, determining a location for replacing the battery of the electric power motion apparatus, and notifying the electric power motion apparatus whose battery needs to be replaced, and the time and location for replacing the battery to a manager of the lease station via the lease application; and when the user returns the electric power motion apparatus via the lease application, enabling the electric power motion apparatus to self check, and terminating the lease.

### CROSS-REFERENCE TO RELATED APPLICATIONS

This application claims priority to China Pat. No. 201811197192.4 filed on Oct. 15, 2018, now pending, which is hereby incorporated by reference in its entirety.

Although incorporated by reference in its entirety, no arguments or disclaimers made in the parent application apply to this divisional application. Any disclaimer that may have occurred during the prosecution of the above-referenced application is hereby expressly rescinded. Consequently, the Patent Office is asked to review the new set of claims in view of all of the prior art of record and any search that the Office deems appropriate.

### TECHNICAL FIELD

Embodiments of the present invention relate to the technical field of lease management, and in particular, relate to a lease management method and system of an electric power motion apparatus.

### BACKGROUND

Surfing is typically a sports item which depends on sea waves and struggles against the sea waves by using high technical skills and good balancing capability of a surfer. In the sea, a surfer has a place suitable for sea waves to lie on his or her back or sit on a surfboard to wait. When suitable sea waves gradually approach, the surfer adjusts the direction of the head of the surfboard, and lie on the back on the surfboard to paddle along the direction of the sea waves, which provides a sufficient speed for the surfboard such that the surfboard maintains at the front of the sea waves. When the sea waves push the surfboard to slide, the surfer stands up, with two legs naturally standing up and the knees being slightly bent. In this way, the surfer controls the way of the surfboard by using the center of gravity of the body, the shoulder and the rear legs. In addition, the surfing is further typically implemented depending on a force given by a boat, which is referred to as traction-based surfing.

With the development of science and technology, in recent years, electric water scooters are come into being. The electric water sliding board is practiced by adding an electric power apparatus on a conventional scooter, wherein the scooter is driven by a force provided by the electric power apparatus. In the electric water scooter, the direction still needs to be controlled based on the center of gravity of the body.

Transport sharing economy is now extending from vehicles, bikes and locomotives to various fields including the electric water scooters. However, with respect to lease of electric scooters currently, in the course of practicing the present invention, the inventors have found that the prior art at least has the following problems:

Water electric scooters need power supplied by a large-capacity battery. With respect to rechargeable batteries commonly used currently, battery states may not be checked (for example, a remaining power amount and a cycle count), such that the maintenance of the batteries is very complicated. Unlike a fuel product to which fuel may be added any time, with respect to the battery, a battery measurement device needs to be carried by a user. However, the conventional battery measurement device may only acquire voltage information of the battery. The voltage information of the battery does not directly represent the remaining power amount of the battery. Management personnels need to determine based on their skills whether the power amount of the battery is sufficient for use for a next time period. If the power amount is insufficient, the battery needs to be replaced.

In addition, the battery of the water electric scooter is generally a power battery which has a large size and weight and thus may not be carried by the user. As such, if the battery needs to be replaced, the user needs to return to the warehouse to take a new battery. This process consumes a large amount of time, and consequently a large amount of maintenance personnels are desired. A large amount of water electric scooters need to be maintained at a lease station, and the maintenance workload increases by geometric progression with the number of scooters maintained at the lease station, which becomes a challenge in promotion of the scooters in the current large-scale lease market. Even if some batteries are equipped with power amount indication, manual operations are needed. In addition, the batteries may only be replaced when the scooters return to the lease station or the maintenance personnels of the scooters need to carry by themselves a large number of batteries for replacement. Since the batteries are heavy, it is very troublesome. If the batteries are insufficient, the maintenance personnels need to return to take more, which is time consuming

Especially in the lease market, lease of the scooters needs to be carried out at a fixed site, such as the lease station. If the maintenance personnels are insufficient, the user needs to carry the heavy electric scooters. As a result, use of the scooters is difficult, and user experience is poor.

It should be noted that the above description of the technical background is only intended to make the technical solutions of the present invention clearer and more complete, and to further facilitate understanding of the present invention by persons skill in the art. Although the technical solutions are elaborated in the background of the present invention, the above technical solutions shall not be considered as commonly known by persons skilled in the art.

### SUMMARY

In view of the above problem, embodiments of the present invention are intended to provide a lease management method and system of an electric power motion apparatus. According to the present invention, a battery state and location information of the electric power motion apparatus at a lease station may be monitored in real time, such that lease management of the electric power motion apparatus is simple and convenient, and hence user experience is improved.

Embodiments of the present invention provide a lease management system of an electric power motion apparatus. The system includes: a base station deployed at a lease station, an electric power motion apparatus connected to the base station by long-distance wireless communication, a smart terminal where a lease application is installed, and a cloud-end management platform, the base station is connected to the cloud-end management platform via a network, the base station is configured to acquire in real time lease information, a battery state and location information of the electric power motion apparatus at the lease station, and report the same to the cloud-end management platform; and the cloud-end management platform is configured to determine an idle time period of the electric power motion apparatus based on the lease information, calculate time for replacing a battery of the electric power motion apparatus based on the battery state, determine a location where the battery of the electric power motion apparatus needs to be replaced based on the location information, and notify the electric power motion apparatus whose battery needs to be replaced, and the time and location for replacing the battery to a manager of the lease station via the lease application. The smart terminal where the lease application is installed is connected to the cloud-end management platform via the network; a user checks idle time periods of the electric power motion apparatus at the lease station via the lease application and reserves lease, and returns the electric power motion apparatus via the lease application; and the manager of the lease station checks in real time the lease information, the battery state and the location information of the electric power motion apparatus at the lease station via the lease application, replaces the battery of the electric power motion apparatus based on the time and location notified by the cloud-end management platform, and performs lease management and maintenance of the electric power motion apparatus at the lease station.

Further, the electric power motion apparatus comprises a power unit. The power unit includes a power module and a power module lock; wherein when the user unlocks the electric power motion apparatus within a lease duration, the power module lock is opened to enable the power module, and when the user returns the electric power motion apparatus, the power module lock is closed to disable the power module.

Further, the electric power motion apparatus further includes a lease management unit, the lease management unit comprising a communication module, a GPS-based positioning module and a direction checking module. The communication module is configured to carry out long-distance wireless communication with the base station, the GPS-based positioning module is configured to acquire the location information of the electric power motion apparatus, and the direction checking module is configured to acquire a direction angle of advancement of the electric power motion apparatus via a built-in direction sensor.

Embodiments of the present invention further provide a management method of an electric power motion apparatus. The method includes: checking, by a user, idle time periods of the electric power motion apparatus at a lease station via a lease application installed on a smart terminal, determining a lease time period, and reserving lease of the electric power motion apparatus; based on the lease reservation, unlocking, by the user, the electric power motion apparatus at the lease station via the lease application within the lease time period to acquire the electric power motion apparatus; in use of the electric power motion apparatus, acquiring, by a cloud-end management platform, lease information, a battery state and location information of the electric power motion apparatus at the lease station via a base station; when a remaining power amount of the electric power motion apparatus is insufficient, sending, by the cloud-end management platform, a prompt message to the user via the lease application, calculating time for replacing a battery of the electric power motion apparatus based on the battery state, determining a location where the battery of the electric power motion apparatus needs to be replaced based on the location information, and notifying the electric power motion apparatus whose battery needs to be replaced, and the time and location for replacing the battery to a manager of the lease station via the lease application; and when the user returns the electric power motion apparatus via the lease application, enabling, by the cloud-end management platform, the electric power motion apparatus to self check via the base station, and terminating the lease of the electric power motion apparatus if a return condition is satisfied and payment is made.

Further, the method further includes: predefining the idle time periods and a reservation coefficient of the idle time periods via the lease application installed on the smart terminal, the reservation coefficient being defined based on big data indicative of busy degree of the lease station; wherein the big data indicative of busy degree of the lease station is data statistically collected by the cloud-end management platform regarding lease quantity and use frequency of the electric power motion apparatus within the lease time period at the lease station; and the number of electric power motion apparatuses that are leaseable at the lease station within the idle time periods in the lease application installed on the smart terminal is calculated by: multiplying the number of actual idle electric power motion apparatuses at the lease station by the reservation coefficient of the idle time periods.

Further, the method further includes: if the cloud-end management platform receives the lease reservation, reducing the number of electric power motion apparatus that are leaseable in the lease reservations within a corresponding idle time period; and if the cloud-end management platform receives cancellation of the lease reservation, increasing the number of electric power motion apparatuses that are leaseable in the lease reservations within the corresponding idle time period.

Further, the method further includes: within a predefined time duration in the lease time period, sending, by the cloud-end management platform, a lease reservation prompt message to the user via the lease application; after the user reaches the lease station, guiding, by the cloud-end management platform, the user to reach a closest electric power motion apparatus via the lease application based on location of the user and the location information of the electric power motion apparatus obtained in real time; arranging a lease identifier on the electric power motion apparatus, and scanning the lease identifier by the smart terminal when the user reaches the electric power motion apparatus; and unlocking the electric power motion apparatus and starting timing if it is determined via the lease application that the lease reservation is within the lease time period.

Further, the method further includes: in use of the electric power motion apparatus, based on use time of the electric power motion apparatus, sending a return prompt message to the user via the lease application when the predefined time duration before expiration of the lease time is reached; based on the location information of the electric power motion apparatus, when the electric power motion apparatus is located outside the lease range of the lease station, sending a return-to-lease-range prompt message to the user, and based on normal adjustment and control, by using a lease control unit, additionally adjusting an advancement direction of the electric power motion apparatus to face towards the lease station and additionally controlling the electric power motion apparatus to advance towards the lease station; and based on the location information and the battery state of the electric power motion apparatus, if the remaining power amount of the electric power motion apparatus is less than or equal to a sum of a power amount for returning to the lease station and a predefined remaining power amount, sending a prompt message indicative of an insufficient power amount to the user, and based on normal adjustment and control, additionally controlling the electric power motion apparatus to decelerate to a speed in a power saving mode, and additionally adjusting the advancement direction of the electric power motion apparatus to face towards the lease station such that the electric power motion apparatus advances towards the lease station.

Further, the calculating time for replacing a battery of the electric power motion apparatus based on the battery state includes: based on a power amount when the timing is started and the use time, calculating, by the cloud-end management platform, the remaining power amount of the electric power motion apparatus, and calculating the time for replacing the battery based on the remaining power amount.

Further, the enabling the electric power motion apparatus to self check via the base station and terminating the lease of the electric power motion apparatus if a return condition is satisfied and payment is made when the user returns the electric power motion apparatus via the lease application includes: when the electric power motion apparatus returns to the lease station and is returned via the lease application, upon receiving a return request, sending, by the cloud-end management platform a return instruction to the electric power motion apparatus such that the electric power motion apparatus performs self-check and terminates the timing, wherein the self-check comprises checking the battery state and integrity of the electronic part; and if the return condition is satisfied, determining the use time based on the time when the timing is started and the time when the timing is terminated, calculating fees based on the use time, paying the fees and terminating the lease of the electric power motion apparatus.

Accordingly, in the lease management method and system of the electric power motion apparatus according to the embodiments of the present invention, with respect to the system, a base station is deployed at a lease station, an electric power motion apparatus at the lease station is connected to the base station by long-distance wireless communication, the base station is connected to a cloud-end management platform via a network, and thus user lease and lease management of the electric power motion apparatus at the lease station are practiced out via a lease application. In this way, the problems that operation cost of the electric power motion apparatuses currently using large power batteries in large-scale lease operation is high and user experience is poor are addressed. Lease information, battery state and location information of each electric power motion apparatus at a lease station may be acquired in real time by using the cloud-end management platform, idle time periods of the electric power motion apparatus may be determined based on then lease information, time for replacing the battery of the electric power motion apparatus may be calculated based on the battery state, location where the battery of the electric power motion apparatus needs to be replaced may be determined based on the location information, and the electric power motion apparatus whose battery needs to be replaced, the time and location for replacing the battery are notified to a manager of the lease station. As such, the user may be prompted to timely return the electric power motion apparatus to the lease range, and the manager may timely replace the battery, such that the maintenance cost of the large-power battery is lowered. By the wireless network plus the lease application, the user may freely lease and return an electric power motion apparatus within the lease range without having to go far. In this way, the transportation workload is reduced, and the user experience is improved.

### BRIEF DESCRIPTION OF THE DRAWINGS

For clearer description of the technical solutions according to the embodiments of the present invention or in the related art, hereinafter, drawings that are to be referred for description of the embodiments or the related art are briefly described. Apparently, the drawings described hereinafter merely illustrate some embodiments of the present invention. Persons of ordinary skill in the art may also derive other drawings based on the drawings described herein without paying any creative effort.

FIG. 1 is a schematic diagram of a lease management system of an electric power motion apparatus according to an embodiment of the present invention; and

FIG. 2 is a flowchart of a lease management method of an electric power motion apparatus according to an embodiment of the present invention.

### DETAILED DESCRIPTION

For clearer description of the objectives, technical solutions and advantages of the embodiments of the present application clearer, the technical solutions according to the embodiments of the present invention are clearly and thoroughly described with reference to the accompanying drawings of the embodiments of the present invention. The described embodiments are merely exemplary ones, but are not all the embodiments of the present invention. Based on the embodiments of the present invention, all other embodiments derived by persons of ordinary skill in the art without any creative efforts shall fall within the protection scope of the present invention. As used in the embodiments of the present invention and the appended claims, the singular forms “a”, “an” and “the” are intended to include the plural forms as well, unless the context clearly indicates otherwise.

An embodiment of the present invention provides a lease management system of an electric power motion apparatus. In practice, the electric power motion apparatus may be an electric scooter, especially a water electric scooter. Nevertheless, other electric power motion apparatuses, such as various electric entertainment devices that may be used on water or in the land, may also be included, as long as these devices are equipped with an electric propelling means and are steered within a specific range of a lease station, for example, small-sized motor boats or the like, which are not specifically limited herein. Different types of electric devices for lease may be equipped with a lease control module, and may be managed in a centralized manner in the lease management system of the electric power motion apparatus.

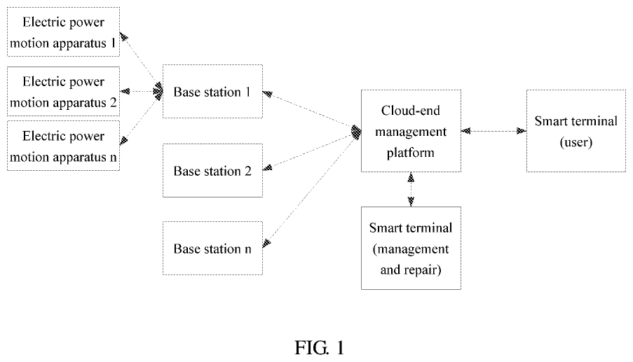

As illustrated in FIG. 1, the lease management system of an electric power motion apparatus includes: a base station deployed at a lease station, an electric power motion apparatus connected to the base station by long-distance wireless communication, a smart terminal where a lease application is installed, and a cloud-end management platform. In this embodiment, the lease station may be an area, for example, a beach; and the electric power motion apparatuses may be distributed in this area. Users may lease or return the electric power motion apparatuses in this area.

The electric power motion apparatus at the lease station is connected to the base station by long-distance wireless communication. In this embodiment, the long-distance wireless communication is preferably narrowband spread spectrum communication, to achieve a large coverage range. The base station is connected to a cloud-end management platform in the Internet via a wired or wireless network. A smart terminal of the user is connected to the cloud-end management platform via a lease application (APP) installed on the smart terminal, such that the user may be communicatively connected to the electric power motion apparatus at the lease station via the lease application.

The electric power motion apparatus includes: a battery pack, a power unit, a lease control unit, an auxiliary steering unit and a controller; wherein the battery pack is configured to supply power for the electric power motion apparatus; the power unit is connected to the battery pack, and configured to propel the electric power motion apparatus and control a speed of the electric power motion apparatus under cooperation of the controller; and the lease control unit is connected to the power unit and the auxiliary steering unit, and configured to acquire location information, an advancement direction and a battery state of the electric power motion apparatus, and additionally adjust and control the electric power motion apparatus under cooperation of the auxiliary steering unit based on normal adjustment and control.

It should be noted that relative to the prior art, a lease control unit is innovatively configured in the electric power motion apparatus according to the embodiment of the present invention. The lease control unit includes a central processing unit (CPU), a communication module, a global positioning system (GPS)-based positioning module, a direction checking module and a direction indicating module. The communication module is configured to communicate with the base station. The GPS-based positioning module is configured to acquire the location information of the electric power motion apparatus. The direction checking module is configured to acquire a current direction angle of advancement of the electric power motion apparatus by using a built-in direction sensor. The direction indicating module is configured to display a direction for returning to a lease station for the user, and the direction indicating module is preferably a light-emitting diode (LED) which serves as a direction indication lamp.

The power unit includes a power module and a power module lock. When the user unlocks the electric power motion apparatus within a lease duration, the power module lock is opened to enable the power module; and when the user returns the electric power motion apparatus, the power module lock is closed to disable the power module.

It should be noted that relative to the prior art, a lease application that may be installed on a smart terminal is innovatively configured according to the embodiment of the present invention. The lease application may include a user-specific lease application and a manager-specific lease application, which may be a user interface and a manager interface of the lease application, which are not specifically limited in the embodiment of the present invention.

The base station acquires in real time lease information, battery state and location information of the electric power motion apparatus, and reports the same to the cloud-end management platform. The cloud-end platform determines idle time periods of the electric power motion apparatus based on the lease information, calculates time for replacing a battery of the electric power motion apparatus based on the battery state, determines location where the battery of the electric power motion apparatus needs to be replaced, and notifies the electric power motion apparatus whose battery needs to be replaced, and the time and location for replacing the battery to a management and maintenance personnel at the lease station via the lease application.

The smart terminal where the lease application is installed is connected to the cloud-end management platform via the network; a user checks idle time periods of the electric power motion apparatus at the lease station via the lease application and reserves lease, and return the electric power motion apparatus via the lease application; and the manager of the lease station checks in real time the lease information, the battery state and the location information of the electric power motion apparatus at the lease station via the lease application, replaces the battery of the electric power motion apparatus based on the time and location notified by the cloud-end management platform, and performs lease management and maintenance of the electric power motion apparatus at the lease station.

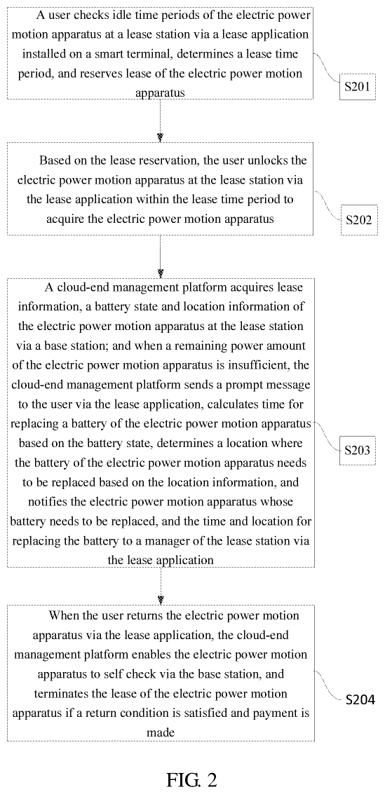

An embodiment of the present invention further provides a lease management method of an electric power motion apparatus. As illustrated in FIG. 2, the method includes the following steps:

Step S201: A user checks idle time periods of the electric power motion apparatus at a lease station via a lease application installed on a smart terminal, determines a lease time period, and reserves lease of the electric power motion apparatus.

In this step, a manager of the lease station predefines the idle time periods and a reservation coefficient of the idle time periods via the lease application installed on the smart terminal. The reservation coefficient is defined based on big data indicative of busy degree of the lease station; wherein the big data indicative of busy degree of the lease station is data statistically collected by the cloud-end management platform regarding lease quantity and use frequency of the electric power motion apparatus within the lease time period at the lease station.

In addition, the number of electric power motion apparatuses that are leaseable at the lease station within the idle time periods in the lease application installed on the smart terminal is calculated by: multiplying the number of actual idle electric power motion apparatuses at the lease station by the reservation coefficient of the idle time periods, or adding the number of actual idle electric power motion apparatuses at the lease station to the predefined number of reserved electric power motion apparatuses. In this way, based on the reservation coefficient and the number of reserved electric power motion apparatuses, the total number of electric power motion apparatuses to be reserved at the lease station may be controlled to not exceed the number of electric power motion apparatuses that are leaseable at the lease station.

The user checks the idle time periods of the electric power motion apparatus at the lease station via the lease application installed on the smart terminal, determines the lease time period, and reserves the lease of the electric power motion apparatus. With respect to lease reservation by the user, if electric power motion apparatuses of only one type are deployed at the lease station, the idle time periods thereof only needs to be distributed and one or a plurality of specific electric power motion apparatuses may not be locked, instead within a determined lease time period, one or a plurality of electric power motion apparatuses are reserved; and if electric power motion apparatuses of a plurality of types are deployed at the lease station, the user needs to determine the idle time periods and the types of the electric power motion apparatuses.

If the user successfully performs a lease reservation, the number of electric power motion apparatus that are leaseable is decreased within the corresponding idle time period. If the user cancels a lease reservation via the lease application, the number of electric power motion apparatuses that are leaseable is increased within the corresponding idle time period.

Step S202: Based on the lease reservation, the user unlocks the electric power motion apparatus at the lease station via the lease application within the lease time period to acquire the electric power motion apparatus.

The cloud-end management platform monitors the electric power motion apparatuses at various lease stations, and the battery states thereof, wherein the battery state includes a remaining power amount and a charge and recharge cycle count. In addition, the cloud-end management platform may also predict a user cycle of the battery and the like consumable accessory and the number of accessories to be replaced by collecting statistics for use time of the electric power motion apparatuses at each lease station, and arrange stock and transportation.

Within a predefined time duration before the lease time period, for example, half an hour before the lease time, a lease reservation prompt message is sent to the user via the lease application. When the user reaches the lease range of the lease station, the user is guided to a closest electric power motion apparatus based on real-time location information of the user and the location information of the electric power motion apparatus.

A lease identifier, for example, a two-dimensional code, is arranged on the electric power motion apparatus. When the user reaches before the electric power motion apparatus, the two-dimensional code of the electric power motion apparatus is scanned. If the lease application determines that the reservation is within the lease time period, the electric power motion apparatus is unlocked and timing is started such that the user uses the electric power motion apparatus within the lease time period. Specifically, the electric power motion apparatus may be unlocked by enabling a power motion lock of the electric power motion apparatus within the lease time.

Step S203: In use of the electric power motion apparatus, a cloud-end management platform acquires lease information, a battery state and location information of the electric power motion apparatus at the lease station via a base station; when the remaining power amount of the electric power motion apparatus is insufficient, the cloud-end management platform sends a prompt message to the user via the lease application, calculates time for replacing a battery of the electric power motion apparatus based on the battery state, determines a location where the battery of the electric power motion apparatus needs to be replaced based on the location information, and notifies the electric power motion apparatus whose battery needs to be replaced, and the time and location for replacing the battery to the manager of the lease station via the lease application.

In this step, in use of the electric power motion apparatus by the user, a lease control unit of the electric power motion apparatus acquires in real time the use time, location information and battery state of the electric power motion apparatus, and reports the same to the cloud-end management platform.

Based on the use time, the cloud-end management platform sends a return prompt message to the user when the predefined time duration before expiration of the lease time is reached. Based on the acquired location information, when the electric power motion apparatus is located outside the lease range of the lease station, a lease range prompt message is sent to the user, and based on normal adjustment and control of the user, the advancement direction of the electric power motion apparatus is additionally adjusted to face towards the lease station such that the electric power motion apparatus advances towards the lease application. Based on the acquired location information and battery state of the electric power motion apparatus, if the remaining power amount of the electric power motion apparatus is less than or equal to a sum of a power amount for returning to the lease station and a predefined remaining power amount, or the remaining power amount of the electric power motion apparatus approaches a minimum power amount for returning to the lease station, a prompt message indicative of an insufficient power amount is sent to the user, and based on normal adjustment and control, the electric power motion apparatus is additionally controlled to decelerate to a speed in a power saving mode, and the advancement direction of the electric power motion apparatus is additionally adjusted to face towards the lease station such that the electric power motion apparatus advances towards the lease station.

In addition, the cloud-end management platform calculates the time for replacing the battery of the electric power motion apparatus based on the battery state, determines the location where the battery of the electric power motion apparatus needs to be replaced based on the location information of the electric power motion apparatus, and notifies the electric power motion apparatus whose battery needs to be replaced, and the time and location for replacing the battery to the manager of the lease station via the lease application. Specifically, if the remaining power amount of the electric power motion apparatus is less than or equal to the sum of the power amount for returning to the lease station and the predefined remaining power amount, or the remaining power amount of the electric power motion apparatus is less than or equal to a product of the power amount for returning to the lease station and a predefined coefficient which is greater than or equal to 1, or the remaining power amount of the electric power motion apparatus approaches a minimum power amount for returning to a return range of the lease station, the cloud-end management platform sends a replace battery prompt message to the manager of the lease station via the lease application, such that the battery is timely replaced.

Step S204: When the user returns the electric power motion apparatus via the lease application, the cloud-end management platform enables the electric power motion apparatus to self check via the base station, and terminates the lease of the electric power motion apparatus if a return condition is satisfied and payment is made.

In this step, when the user returns the electric power motion apparatus to the lease station, and returns the electric power motion apparatus via the lease application, the cloud-end management platform sends a return instruction to the electric power motion apparatus upon receiving a return request message. Upon receiving the return instruction, the electric power motion apparatus performs self-check and terminates the timing. The self-check includes checking the battery state and integrity of the electronic part, for example, checking the battery state to determine whether to replace the battery, and checking integrity of the electronic part to determine whether the power motion is caught by water plants and needs to be cleared and maintained. If the return condition is satisfied, for example, the remaining power amount is greater than the predefined power amount and the electronic part operates properly, fees are calculated based on the use time and a payment procedure is started.

The payment procedure may include starting a deposit payment during the lease reservation, and completing the lease reservation procedure upon successful deposit payment. In returning of the electric power motion apparatus, if the return condition is satisfied, the use time is determined based on the time when the timing is started and the time when the timing is terminated, the fees are calculated based on the use time and a fees payment procedure is started, and the deposit is returned upon successful fees payment and hence the electric power motion apparatus is successfully leased. Nevertheless, the deposit payment procedure may not be used. Instead, the fees are calculated based on the use time and the fees payment is made after the electric power motion apparatus is returned, such that the electric power motion apparatus is successfully leased.

The specific technical details involved in the lease management method of the electric power motion apparatus are similar to those in the lease management system of the electric power motion apparatus. The technical effects achieved in the embodiments of the lease management system of the electric power motion apparatus are likewise achieved in the embodiments of the lease management method of the electric power motion apparatus. The details are not given herein any further for brevity. Correspondingly, the relevant technical details mentioned in the embodiments of the lease management method of the electric power motion apparatus may also be applied to the embodiments of the lease management system of the electric power motion apparatus.

Accordingly, in the lease management method and system of the electric power motion apparatus according to the embodiments of the present invention, with respect to the system, a base station is deployed at a lease station, an electric power motion apparatus at the lease station is connected to the base station by long-distance wireless communication, the base station is connected to a cloud-end management platform via a network, and thus user lease and lease management of the electric power motion apparatus at the lease station are practiced out via a lease application. In this way, the problems that operation cost of the electric power motion apparatuses currently using large power batteries in large-scale lease operation is high and user experience is poor are addressed. Lease information, battery state and location information of each electric power motion apparatus may be acquired in real time by using the cloud-end management platform, idle time periods of the electric power motion apparatus may be determined based on then lease information, time for replacing the battery of the electric power motion apparatus may be calculated based on the battery state, location where the battery of the electric power motion apparatus needs to be replaced may be determined based on the location information, and the electric power motion apparatus whose battery needs to be replaced, the time and location for replacing the battery are notified to a manager of the lease station. As such, the user may be prompted to timely return the electric power motion apparatus to the lease range, and the manager may timely replace the battery, such that the maintenance cost of the large-power battery is lowered. By the wireless network plus the lease application, the user may freely lease and return an electric power motion apparatus within the lease range without having to go far. In this way, the transportation workload is reduced, and the user experience is improved.

Various embodiments in the specification are described in a progressive manner. The same or similar parts between the embodiments may be referenced to each other. In each embodiment, the portion that is different from other embodiments is concentrated and described.

Finally, it should be noted that, the above descriptions of the embodiments of the present invention are provided for demonstration to persons skilled in the art, instead of exhaustively listing all the embodiments or limiting the present invention to a single disclosed embodiment. In view of the above, various replacements and variations to the present invention are apparent to persons skilled in the art. Therefore, although some alternative embodiments have been discussed in detail, other embodiments are apparent or can be readily derived by a person skilled in the art. The present invention is intended to cover all the replacements, modifications and variations to the present invention that have been discussed here as well as other embodiments consistent with the spirit and scope of the present invention.

What is claimed is:

1. A lease management system of an electric power motion apparatus, comprising: a base station deployed at a lease station, an electric power motion apparatus connected to the base station by long-distance wireless communication, a smart terminal where a lease application is installed, and a cloud-end management platform; wherein
the base station is connected to the cloud-end management platform via a network, the base station is configured to acquire in real time lease information, a battery state and location information of the electric power motion apparatus at the lease station, and report the same to the cloud-end management platform; and
the cloud-end management platform is configured to determine an idle time period of the electric power motion apparatus based on the lease information, calculate time for replacing a battery of the electric power motion apparatus based on the battery state, determine a location where the battery of the electric power motion apparatus needs to be replaced based on the location information, and notify the electric power motion apparatus whose battery needs to be replaced, and the time and location for replacing the battery to a manager of the lease station via the lease application; and
the smart terminal where the lease application is installed is connected to the cloud-end management platform via the network; a user checks idle time periods of the electric power motion apparatus at the lease station via the lease application and reserves lease, and returns the electric power motion apparatus via the lease application; and
the manager of the lease station checks in real time the lease information, the battery state and the location information of the electric power motion apparatus at the lease station via the lease application, replaces the battery of the electric power motion apparatus based on the time and location notified by the cloud-end management platform, and performs lease management and maintenance of the electric power motion apparatus at the lease station.

2. The lease management system of an electric power motion apparatus according to claim 1, wherein the electric power motion apparatus comprises a power unit; wherein
the power unit comprises a power module and a power module lock; wherein when the user unlocks the electric power motion apparatus within a lease duration, the power module lock is opened to enable the power module, and when the user returns the electric power motion apparatus, the power module lock is closed to disable the power module.

3. The lease management system of an electric power motion apparatus according to claim 1, wherein the electric power motion apparatus further comprises a lease management unit, the lease management unit comprising a communication module, a GPS-based positioning module and a direction checking module; wherein
the communication module is configured to carry out long-distance wireless communication with the base station, the GPS-based positioning module is configured to acquire the location information of the electric power motion apparatus, and the direction checking module is configured to acquire a direction angle of advancement of the electric power motion apparatus via a built-in direction sensor.

4. A lease management method of an electric power motion apparatus, comprising:
checking, by a user, idle time periods of the electric power motion apparatus at a lease station via a lease application installed on a smart terminal, determining a lease time period, and reserving lease of the electric power motion apparatus;
based on the lease reservation, unlocking, by the user, the electric power motion apparatus at the lease station via the lease application within the lease time period to acquire the electric power motion apparatus;
in use of the electric power motion apparatus, acquiring, by a cloud-end management platform, lease information, a battery state and location information of the electric power motion apparatus at the lease station via a base station;
when a remaining power amount of the electric power motion apparatus is insufficient, sending, by the cloud-end management platform, a prompt message to the user via the lease application, calculating time for replacing a battery of the electric power motion apparatus based on the battery state, determining a location where the battery of the electric power motion apparatus needs to be replaced based on the location information, and notifying the electric power motion apparatus whose battery needs to be replaced, and the time and location for replacing the battery to a manager of the lease station via the lease application; and
when the user returns the electric power motion apparatus via the lease application, enabling, by the cloud-end management platform, the electric power motion apparatus to self check via the base station, and terminating the lease of the electric power motion apparatus if a return condition is satisfied and payment is made.

5. The lease management method of an electric power motion apparatus according to claim 4, further comprising: predefining the idle time periods and a reservation coefficient of the idle time periods via the lease application installed on the smart terminal, the reservation coefficient being defined based on big data indicative of busy degree of the lease station; wherein the big data indicative of busy degree of the lease station is data statistically collected by the cloud-end management platform regarding lease quantity and use frequency of the electric power motion apparatus within the lease time period at the lease station; and
the number of electric power motion apparatuses that are leaseable at the lease station within the idle time periods in the lease application installed on the smart terminal is calculated by: multiplying the number of actual idle electric power motion apparatuses at the lease station by the reservation coefficient of the idle time periods.

6. The lease management method of an electric power motion apparatus according to claim 5, further comprising: if the cloud-end management platform receives the lease reservation, reducing the number of electric power motion apparatus that are leaseable in the lease reservations within a corresponding idle time period; and
if the cloud-end management platform receives cancellation of the lease reservation, increasing the number of electric power motion apparatuses that are leaseable in the lease reservations within the corresponding idle time period.

7. The lease management method of an electric power motion apparatus according to claim 6, further comprising: within a predefined time duration before the lease time period, sending, by the cloud-end management platform, a lease reservation prompt message to the user via the lease application;
after the user reaches the lease station, guiding, by the cloud-end management platform, the user to reach a closest electric power motion apparatus via the lease application based on location of the user and the location information of the electric power motion apparatus obtained in real time;
arranging a lease identifier on the electric power motion apparatus, and scanning the lease identifier by the smart terminal when the user reaches the electric power motion apparatus; and
unlocking the electric power motion apparatus and starting timing if it is determined via the lease application that the lease reservation is within the lease time period.

8. The lease management method of an electric power motion apparatus according to claim 7, further comprising: in use of the electric power motion apparatus, based on use time of the electric power motion apparatus, sending a return prompt message to the user via the lease application when the predefined time duration before expiration of the lease time is reached;
based on the location information of the electric power motion apparatus, when the electric power motion apparatus is located outside the lease range of the lease station, sending a return-to-lease-range prompt message to the user, and based on normal adjustment and control, by using a lease control unit, additionally adjusting an advancement direction of the electric power motion apparatus to face towards the lease station and additionally controlling the electric power motion apparatus to advance towards the lease station; and
based on the location information and the battery state of the electric power motion apparatus, if the remaining power amount of the electric power motion apparatus is less than or equal to a sum of a power amount for returning to the lease station and a predefined remaining power amount, sending a prompt message indicative of an insufficient power amount to the user, and based on normal adjustment and control, additionally controlling the electric power motion apparatus to decelerate to a speed in a power saving mode, and additionally adjusting the advancement direction of the electric power motion apparatus to face towards the lease station such that the electric power motion apparatus advances towards the lease station.

9. The lease management method of an electric power motion apparatus according to claim 8, wherein the calculating time for replacing a battery of the electric power motion apparatus based on the battery state comprises:
based on a power amount when the timing is started and the use time, calculating, by the cloud-end management platform, the remaining power amount of the electric power motion apparatus, and calculating the time for replacing the battery based on the remaining power amount.

10. The lease management method of an electric power motion apparatus according to claim 9, wherein the enabling the electric power motion apparatus to self check via the base station and terminating the lease of the electric power motion apparatus if a return condition is satisfied and payment is made when the user returns the electric power motion apparatus via the lease application comprises:
when the electric power motion apparatus returns to the lease station and is returned via the lease application, upon receiving a return request, sending, by the cloud-end management platform a return instruction to the electric power motion apparatus such that the electric power motion apparatus performs self-check and terminates the timing, wherein the self-check comprises checking the battery state and integrity of the electronic part; and
if the return condition is satisfied, determining the use time based on the time when the timing is started and the time when the timing is terminated, calculating fees based on the use time, paying the fees and terminating the lease of the electric power motion apparatus.
